(19) United States
(12) Patent Application Publication
(10) Pub. No.: US 2021/0260525 A1
(43) Pub. Date: Aug. 26, 2021

(54) METHOD AND SYSTEM FOR MOCVD EFFLUENT ABATEMENT

(71) Applicants: Gang HE, Sunnyvale, CA (US); Lori WASHINGTON, Sunnyvale, CA (US); Liqiang YAO, Beijing (CN); Jianhui NAN, Beijing (CN); Xinyun ZHANG, Beijing (CN); UTICA LEASECO, LLC, Rochester Hills, MI (US); DONGTAI HI-TECH EQUIPMENT TECHNOLOGY CO., LTD., Beijing (CN)

(72) Inventors: Gang HE, Sunnyvale, CA (US); Lori WASHINGTON, Sunnyvale, CA (US); Liqiang YAO, Beijing (CN); Jianhui NAN, Beijing (CN); Xinyun ZHANG, Beijing (CN)

(21) Appl. No.: 17/256,577

(22) PCT Filed: Jun. 29, 2018
(86) PCT No.: PCT/CN2018/093525

§ 371 Date: Dec. 28, 2020

(51) Int. Cl. B01D 53/75; B01D 53/00; B01D 53/24; C23C 16/44; B01D 53/64; B01D 8/00

(52) U.S. Cl. CPC B01D 53/75; B01D 53/005; B01D 53/002; B01D 53/24; B01D 2258/0216; B01D 53/64; B01D 8/00; B01D 2257/108; B01D 2257/553; C23C 16/4412

(57) ABSTRACT

The disclosure describes various aspects of a metal organic chemical vapor deposition (MOCVD) effluent abatement process. In an aspect, a system for removing toxic waste from an exhaust stream includes a first cold trap that operates at a first pressure and condenses toxic materials in the exhaust stream for removal as solid waste; a pump connected to the first cold trap that increases a pressure of the exhaust stream; a hot cracker connected to the pump that decomposes toxic materials remaining in the exhaust stream after the first cold trap; a second cold trap connected to the hot cracker that operates at a second pressure higher than the first pressure and condenses the decomposed toxic materials remaining in the exhaust stream for removal as solid waste; and a scrubber connected to the second cold trap that absorbs toxic materials remaining in the exhaust stream after the second cold trap.

### BACKGROUND OF THE DISCLOSURE

Aspects of the present disclosure generally relate to techniques for removing toxic materials from an exhaust stream, and more particularly to a method and a system for the abatement of effluents from a metal organic chemical vapor depositing (MOCVD) process.

When using MOCVD techniques it is necessary to treat the exhaust gas to remove toxic materials, a process generally referred to as effluent abatement. For GaAs MOCVD operations, these toxic materials include species that contain arsenic (different forms of arsenic such as arsine gas (AsH₃) and arsenic vapors) and some amounts of gallium. In the affluent abatement process, exhaust from the MOCVD operation is first passed through a cold trap to condense and collect some of the toxic materials. The output from the cold trap goes through a pump to increase the pressure and then possibly additional cold traps to ensure that all condensable material is collected and removed. Subsequently, a scrubber (e.g., wet or dry scrubber) is used to absorb any remaining arsine gas or arsenic left in the exhaust gas. Any hydrogen left in the gas is then burned to finalize the effluent abatement process.

This process, however, is that is not generally intended for large scale (i.e., high volume/high throughput) manufacturing and issues tend to arise as the components of the process are not optimized for such operations.

Therefore, it is therefore desirable to modify the MOCVD effluent abatement process, and some of its components, to handle with little maintenance the large amounts of toxic materials produced by high volume operations.

### SUMMARY OF THE DISCLOSURE

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its purpose is to present some concepts of one or more aspects in a simplified form as a prelude to the more detailed description that is presented later.

A new GaAs MOCVD effluent abatement process is proposed that uses novel cold traps and hot cracker to handle, with little maintenance, large amounts of toxic materials produced by high volume operations.

In an aspect of the disclosure, a system for removing toxic waste from an exhaust stream produced by a high-volume MOCVD operation includes a first cold trap configured to operate at a first pressure and condense and separate toxic materials in the exhaust stream for removal as solid waste; a pump connected to the first cold trap and configured to increase a pressure of the exhaust stream; a hot cracker connected to the pump and configured to decompose toxic materials remaining in the exhaust stream after the first cold trap; a second cold trap connected to the hot cracker and configured to operate at a second pressure higher than the first pressure and condense and separate the decomposed toxic materials remaining in the exhaust stream for removal as solid waste; and a scrubber connected to the second cold trap and configured to absorb toxic materials remaining in the exhaust stream after the second cold trap. The system can further include a burn box connected to the scrubber and configured to remove flammable gas (e.g., hydrogen) from the exhaust stream.

In an aspect of the disclosure, a method for removing toxic waste from an exhaust stream produced by a high-volume MOCVD operation includes condensing and separating, at a first cold trap configured to operate at a first pressure, toxic materials in the exhaust stream for removal as solid waste; increasing, at a pump connected to the first cold trap, a pressure of the exhaust stream; decomposing, at a hot cracker connected to the pump, toxic materials remaining in the exhaust stream after the condensing by the first cold trap; condensing and separating, at a second cold trap connected to the hot cracker and configured to operate at a second pressure higher than the first pressure, the decomposed toxic materials remaining in the exhaust stream for removal as solid waste; and absorbing, at a scrubber connected to the second cold trap, toxic materials remaining in the exhaust stream after the condensing by the second cold trap. The method can further include removing, at a burn box connected to the scrubber, flammable gas (e.g., hydrogen) from the exhaust stream.

Additional aspects related to methods and systems associated with MOCVD effluent abatement are also described.

### BRIEF DESCRIPTION OF THE DRAWINGS

The appended drawings illustrate only some implementation and are therefore not to be considered limiting of scope.

FIG. 1 is a diagram that illustrates an example of an MOCVD exhaust processing system in accordance with aspects of this disclosure.

FIG. 2 is a diagram that illustrates an example of a hot cracker for use in an MOCVD exhaust processing system in accordance with aspects of this disclosure.

FIGS. 3A and 3B are diagrams that illustrate an example of a cracking zone in a hot cracker in accordance with aspects of this disclosure.

FIG. 4 is a diagram that illustrates an example of a cold trap for use in an MOCVD exhaust processing system in accordance with aspects of this disclosure.

FIG. 5 is a diagram that illustrates another example of a cold trap for use in an MOCVD exhaust processing system in accordance with aspects of this disclosure.

FIG. 6 is a flow chart that illustrates an example of a method for MOCVD effluent abatement in accordance with aspects of this disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known components are shown in block diagram form in order to avoid obscuring such concepts.

In this disclosure, the terms “exhaust gas,” “exhaust stream,” “gas stream,” and “exhaust” may be used interchangeably to refer to a flow of one or more gases, particles, and/or materials resulting from an MOCVD process and that need some form of treatment prior to being discharged.

As described above, the exhaust stream or exhaust gas from an MOCVD process contains many forms of toxic materials so it needs to be treated before it is discharged. For GaAs MOCVD, the exhaust stream can include species that contain mostly arsenic (As) and some amount of gallium (Ga). The arsenic can come in the form of arsine gas (AsH₃) or in the form of arsenic vapors, for example. The vapors can be condensed into a solid using a cold trap, and then it goes through a pump to increase the pressure. There may be additional cold traps to collect as much as possible of the condensable toxic material. Subsequently the exhaust gas can go through a scrubber, which can be a dry scrubber or a wet scrubber, to absorb arsine gas or arsenic from the exhaust gas. What comes out of the scrubber is generally clean and can be directly discharged or discharged after flammable gases have been diluted or burned out.

Various issues arise with conventional treatment of the exhaust from a GaAs MOCVD process is that for high volume operations, such as those needed for mass production of optoelectronic devices made of GaAs. For example, cold traps get filled up very quickly and need to be cleaned up regularly. Typical cold traps have very complicated internal structures that makes them difficult to clean. Cold traps tend not to be very efficient in the removal of toxic materials, leaving a significant amount of the removal to be done by the scrubber. The absorber material in the scrubber (e.g., for a dry scrubber) gets saturated quickly and needs to be thrown away and replaced regularly. If the scrubber is a wet scrubber, then the liquid becomes toxic rapidly and needs to be treated before it is discharged.

The solution is then to make modifications to the system handing the GaAs MOCVD exhaust stream to enable the system to operate for a long time and at large volumes without the need for regular maintenance. To achieve this, one approach is to try to capture the material in its most concentrated form to minimize maintenance and the amount of toxic material that is generated. Therefore, one of the objectives is to capture as much as possible of the toxic, hazardous materials in condensed form, and then rely on the scrubber just as a final, lighter removal process where the absorber material used by the scrubber will take a much longer time to saturate.

As described above, a new GaAs MOCVD effluent abatement process/system is proposed that uses novel cold traps and hot cracker to handle, with little maintenance, large amounts of toxic materials produced by high volume operations. This process/system allows capture of the largest amount of toxic materials in the most concentrated form possible (e.g., at cold traps) and thus reduce the amount of toxic materials captured at the end of the process (e.g., at a scrubber).

Existing cold traps have the problem that they are hard to service. Sometimes the solid waste condenses in one spot and the cold trap needs to be placed off line for cleaning even though it is not full. Thus, the capacity of the cold trap is not limited by its size but by condensation points. Also, cold traps currently use one or more filters, which are not only difficult to clean, but when one of the filters clogs up it changes the pressure and the gas flow in the trap, limiting its effectiveness. In addition, existing cold traps use coils to cool down, but these coils are also difficult to clean.

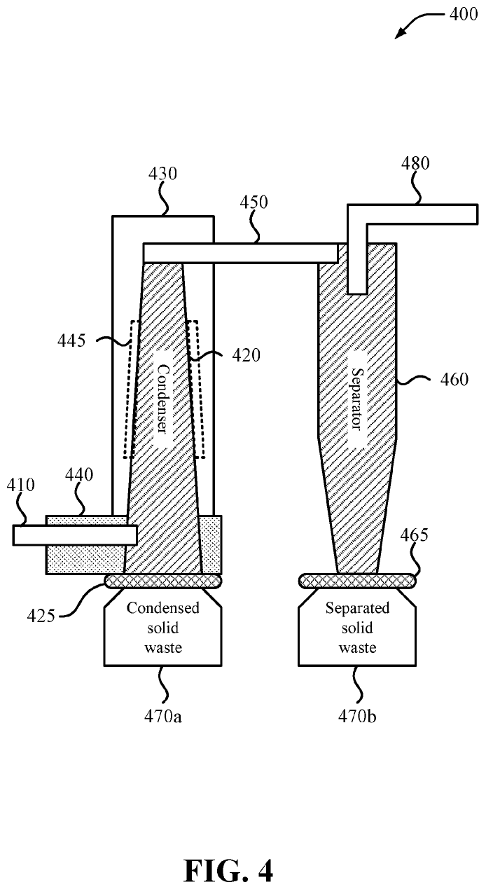

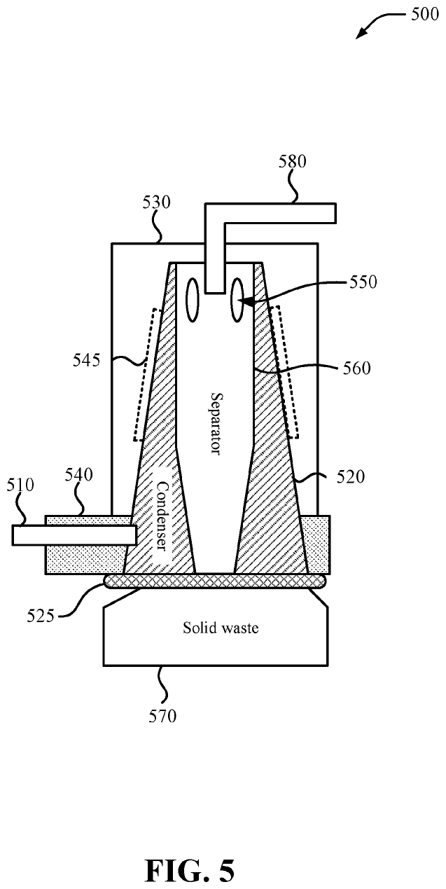

To overcome some of these issues, a novel cold trap configuration is proposed as described in more detail below (see e.g., FIGS. 4 and 5). This novel cold trap uses a two-stage or two-section set up to handle the different types of nucleation or particle formation (e.g., heterogeneous nucleation on surfaces or homogeneous nucleation in the gas phase) that occur when the gas is cooled down. The first stage includes a condenser (e.g., a cyclone condenser) in which a vortex is created by introducing the inlet gas perpendicular to the sidewall surface of an inverted or tapered structure. The sidewalls of the condenser are cooled down and deposits (e.g., heterogeneous nucleation) on the cold sidewalls can be made to easily fall down (e.g., by using flash heating, sonic energy, or mechanical scraping). The speed of the vortex depends on the size/diameter of the condenser.

The second stage or section in the cold trap also includes a structure, referred to as a separator, that can create a cyclone or vortex (e.g., cyclone separator) from which any remaining particles in the gas (e.g., homogeneous nucleation) can be separated into a removable solid waste container. The solid waste container may be different or the same as one used to collect the condensed solid waste from the condenser.

In an alternative configuration, the separator is designed to be positioned within or inside the condenser, with the overall operation being similar to that described above.

The different two-stage or two-section cold trap configurations described above may be used for both low pressure and atmospheric pressure cold traps as part of the new GaAs MOCVD effluent abatement process/system.

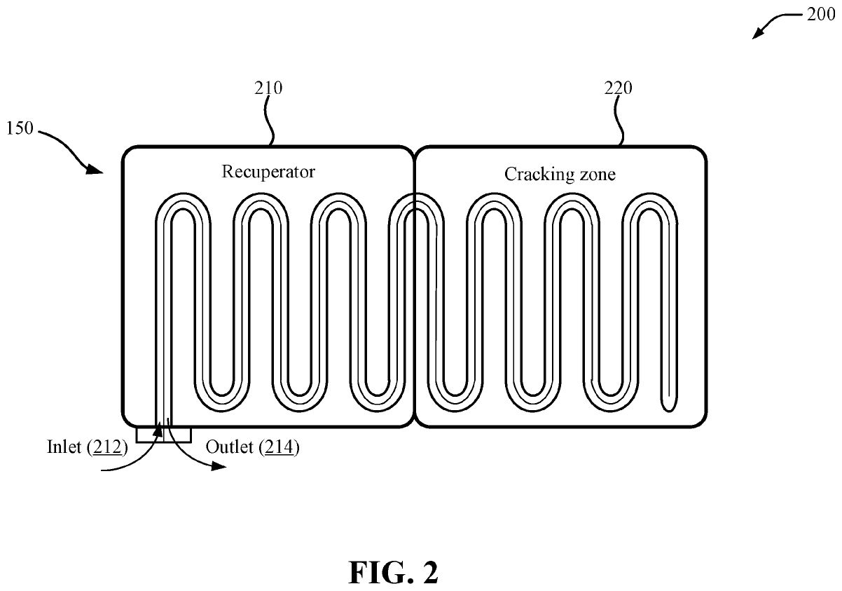

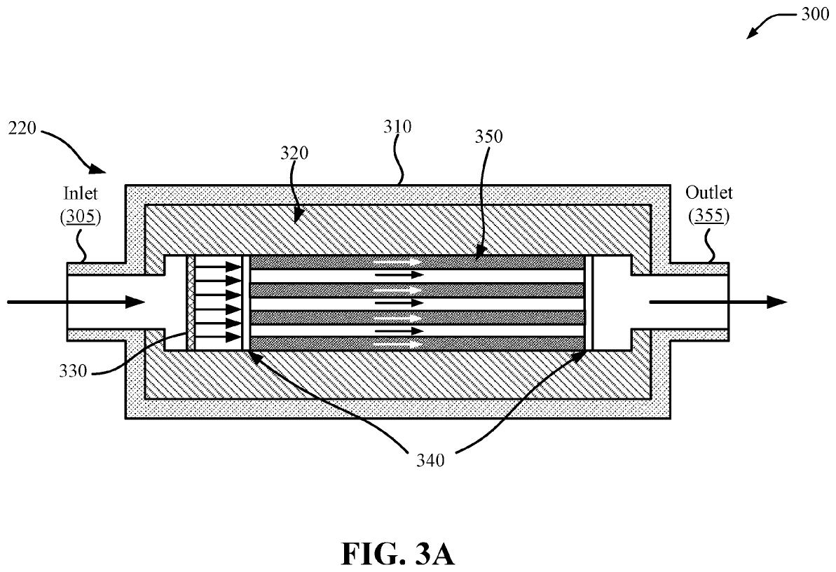

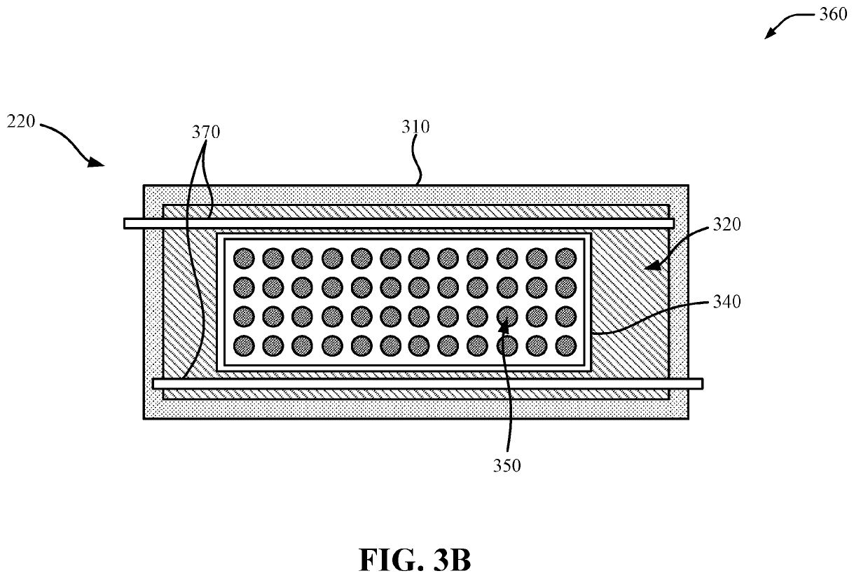

A novel hot cracker is also proposed that can be used at atmospheric pressure between two cold traps to ensure that most of the arsine gas and arsenic that still remains in the exhaust gas after a first cold trap is cracked (e.g., broken down) before going to a second cold trap (i.e., at atmospheric pressure) so that the second cold trap can condense and remove almost all of the remaining solid waste material (e.g., toxic materials). Having a hot cracker that can handle high volume operations is difficult because of the challenges of heating up a large space (needing to heat the exhaust gas as high as 600° C.) and using energy efficiently in doing so. The hot cracker being proposed and described in more detail below (see e.g., FIGS. 2, 3A, 3B) includes two zones or sections: a recuperator (e.g., an insulated thermal recuperator), and a cracking zone (e.g., a high-temperature cracking zone). The recuperator works as a distributed heat exchange to allow an incoming gas stream or exhaust stream received at an inlet to be pre-heated by using a heated output of the cracking zone before the incoming gas stream reaches the cracking zone. This approach allows for a larger volume in the cracking zone since less heating is needed in the cracking zone, resulting in more efficient energy utilization. This dual-zone, dual-section (two-zone, two-section) hot cracker can also be configured to perform catalyzed cracking.

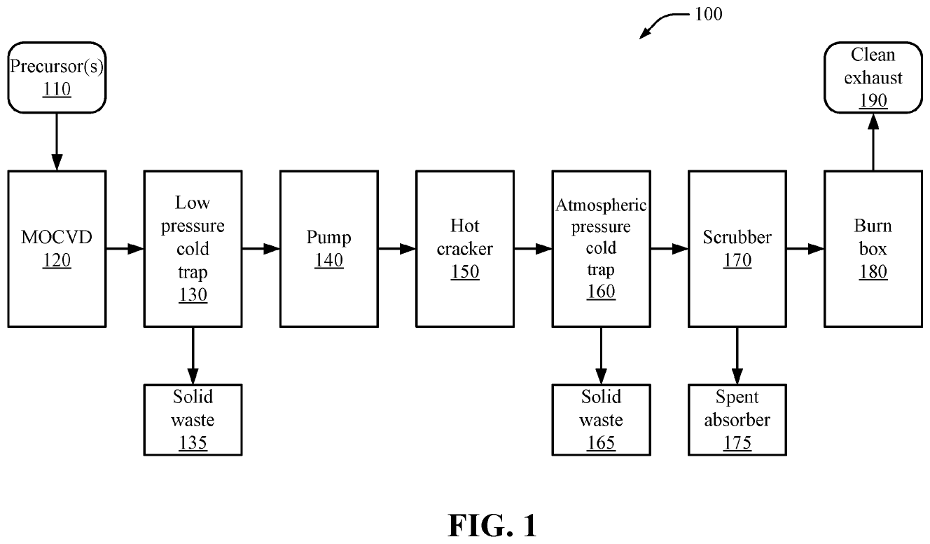

Further details related to the new GaAs MOCVD effluent abatement process/system as well as the proposed cold traps and hot cracker configurations are provided below in connection with FIGS. 1-6.

FIG. 1 shows a diagram 100 describing an example of an MOCVD exhaust processing or effluent abatement system. While this system is suitable for processing the exhaust gas produced by GaAs MOCVD operations, it may also be suitable to handle the exhaust gas from other similar operations. In this system, precursor gas(es) 110 are provided to a GaAs MOCVD processing operation, MOCVD 120. The precursor gas(es) can include arsine gas (AsH₃), for example. The exhaust stream or exhaust gas that remains after the MOCVD 120 are provided to a low pressure cold trap 130. The exhaust stream can include a mixture of vapor and gas species. The low pressure cold trap 130 operates at a pressure level that is lower than an atmospheric pressure level of an atmospheric pressure cold trap 160 further down in the system. The low press pressure cold trap 130 is configured to condense and/or separate some of the toxic materials (e.g., arsenic forms) in the exhaust stream or exhaust gas. The condensed and/or separated material is stored as solid waste 135 for easy removal or cleaning. The low pressure cold trap 130 is configured to maximize the holding capacity of toxic material that it can collect and store, and to simplify the process of removing the toxic material that is collected.

The exhaust stream or exhaust gas that comes out of the low pressure cold trap 130 has fewer toxic materials to help protect a pump 140, which in turn is used to increase the pressure level of the exhaust stream to that of the atmospheric pressure cold trap 160.

The output of the pump 140, which still contains a mixture of toxic gas and vapors, is provided to a hot cracker 150 the cracks the residual precursors in the exhaust stream before the exhaust stream is provided to the atmospheric pressure cold trap 160 to condense and/or separate (e.g., remove) solid toxic materials. That is, the hot cracker 150 is used to decompose the toxic gases into forms that can be more easily condensed in the atmospheric pressure cold trap 160 rather than absorbed in a scrubber. For example, the hot cracker 150 will crack most of the arsine gas into arsenic, which is then turned into solid waste at the atmospheric pressure cold trap 160. Like the low pressure cold trap 130, the atmospheric pressure cold trap 160 is configured to maximize the holding capacity of toxic material that it can collect and store (e.g., solid waste 165), and to simplify the process of removing the toxic material that is collected.

The exhaust stream that is passed from the MOCVD 120 to atmospheric pressure cold trap 160 may be heated between each stage to avoid condensation that may clog or block passage of the exhaust stream.

Following the atmospheric pressure cold trap 160 there is a final cleaning step provided by a scrubber 170 in which an absorber material removes all residual toxic materials. Once the absorber material is full (whether it is a solid absorber or a liquid absorber), any spent absorber material, spent absorber 175, can be removed and replaced.

Finally, a burn box 180 can be used to eliminate all flammable gas such as hydrogen, for example, by burning the gas to remove it from the exhaust stream. The output of the burn box 180 is a clean exhaust 190 that can be released.

FIG. 2 shows a diagram 200 illustrating an example of the hot cracker 150 in FIG. 1. The hot cracker 150 is configured to handle high volume operations and to use energy efficiently in doing so. The hot cracker 150 includes two zones or sections, a recuperator 210 and a cracking zone 220. The recuperator 210 can be an insulated thermal recuperator that is configured to work as a distributed heat exchange to allow an incoming exhaust stream or exhaust gas from an inlet 212 to be pre-heated by using an output of the cracking zone 220 (e.g., heated, cracked exhaust stream) before the incoming exhaust stream reaches the cracking zone 220. This approach allows for a larger volume of exhaust to be processed in the cracking zone 220 since less heating is needed in the cracking zone 220. After being heated by the cracking zone 220, the outgoing exhaust stream is cooled down by the recuperator 210 before it leaves the hot cracker 150 through an outlet 214.

The cracking zone 220 is a high-temperature cracking zone that can operate as high as 600° C. when heating the exhaust stream to further decompose the toxic materials (e.g., decompose arsine gas) in the exhaust stream. This dual-zone, two-zone (dual-section. two-section) hot cracker 150 can also be configured to perform catalyzed cracking by including one or more catalysts within at least the cracking zone 220.

FIGS. 3A and 3B show diagrams 300 and 360 that illustrate one possible implementation of the cracking zone 220 in the hot cracker 150 in FIG. 1. The diagram 300 describes a cross-sectional view along a longitudinal direction of the implementation of the cracking zone 220, while the diagram 360 describes a describes a cross-sectional view along a lateral direction. The cracking zone 220 can be referred to as a thermal decomposition chamber. In this example, the cracking zone or thermal decomposition chamber 220 includes a thermal baffle 310 that is installed outside a chamber 320. One or more heating rods 370 (see the diagram 300 in FIG. 3B) are provided inside the chamber 320 to heat up the chamber 320 and the one or more tubes 350 to a set temperature. The locating plate 340 guarantees (e.g., fixes) the position of the tubes 350 within the chamber 320. The exhaust stream or exhaust gas enters the chamber 320 through an inlet 305 and the exhaust stream is then evenly distributed by a diffuser plate 330. The exhaust stream or exhaust gas flows through center holes along the length of the tubes 350 as well as through the spaces between the tubes 350. The exhaust stream is in full contact with both the inner walls and the outer walls of the tubes 350 and is heated up by heat transfer. The tubes 350 can be made of steel or any other materials that is a good heat conductor. After being heated by the tubes 350, the exhaust stream exists the cracking zone 220 via an outlet 355.

FIG. 4 shows a diagram 400 that illustrates an example of a cold trap, which can be either the low pressure cold trap 130 or the atmospheric pressure cold trap 160 in the diagram 100 in FIG. 1. In this example, the cold trap includes two sections, a condenser 420 and a separator 460. The exhaust stream enters the condenser 420 through an inlet 410 positioned at a lower portion of the condenser 420 and perpendicular to a side a sidewall surface of the inverted structure that is the condenser 420 to create a vortex. This vortex, as described above, causes the toxic materials in the exhaust stream to nucleate, where heterogeneous nucleation produces a coating or deposit on the sidewalls of the inverted (tapered) structure while homogeneous nucleation remains in the gas phase and is passed to the separator 460 through a connector 450.

The condenser 420, which can be referred to as a cyclone condenser or a cold-wall cyclone condenser because of the vortex formed within by the exhaust stream, can have a cooling component 430 that cools an upper portion of the condenser 420 to ensure that the sidewalls are cold for the heterogeneous nucleation to condense on the sidewalls. The cooling component 430 can create a thermal profile that allows for the condensation to spread out over the height of the condenser 420. The condenser 420 can also include a heating component 440 that heats a lower portion of the condenser 420 to ensure that no deposits are formed in this portion to avoid clogging or blocking of the inlet 410.

The smooth, inverted (tapered) sidewall structure of the condenser 420 allows for the easy removal of any deposits that collect on the sidewalls. Optionally, a removal component 445 may be used to apply a flash heating to the sidewalls of the condenser 420 or to provide sonic energy that will loosen up the condensed deposits on the sidewalls so that they can easily fall into a removable component such as a condensed solid waste container 470a through a waste removal gate valve 425 that can be closed when the condensed solid waste container 470a is removed to dispose of the solid waste. Optionally, any deposits on the sidewalls can be mechanically removed by, for example, scraping the inner walls of the condenser 420.

The separator 460 receives the exhaust stream with the homogeneous nucleation (e.g., toxic particles) from the condenser 420 and, similar to the condenser 420, a vortex can be formed to separate the homogeneous nucleation of toxic materials from the exhaust stream. Accordingly, the separator 460 may also be referred to as a cyclone separator or a cyclone particle separator. The separated materials can easily fall into a removable component such as a separated solid waste container 470b through a waste removal gate valve 465 that can be closed when the separated solid waste container 470b is removed to dispose of the solid waste.

The separator 460 can be a multi-stage separator (i.e., there could be multiple separating stages with different separator structures) to ensure near-complete solid waste removal. Moreover, particle filtration may be included in the final stage of the multi-stage separation process.

The cold exhaust stream or gas exits the separator 460 though an outlet 480 at the top of the separator 460 to be provided to a next stage of processing (e.g., to the pump 140 or the scrubber 170).

FIG. 5 shows a diagram 500 that illustrates another example or configuration of a cold trap in which the separator is positioned (integrated) within the condenser. For example, the cold trap configuration in the diagram 500 includes, like the one in the diagram 400, an inlet 510, a condenser 520 (e.g., a cyclone condenser or a cold-wall cyclone condenser), a heating component 540, a cooling component 530, an optional removal component 545, a separator 560 (e.g., a cyclone separator or a cyclone particle separator), and an outlet 580. Different from the cold trap configuration in the diagram 400, there is a single removable component, a solid waste 570, that can be used to collect both the condensed and separated solid waste produced by the condenser 520 and the separator 560, respectively. A waste removal gate valve 525 that can be closed when the solid waste container 570 is removed to dispose of the solid waste.

The separator 560 can be disposed within the condenser 520 and the two can be connected through holes 550 instead of using a connector such as the connector 450 used in the example in the diagram 400.

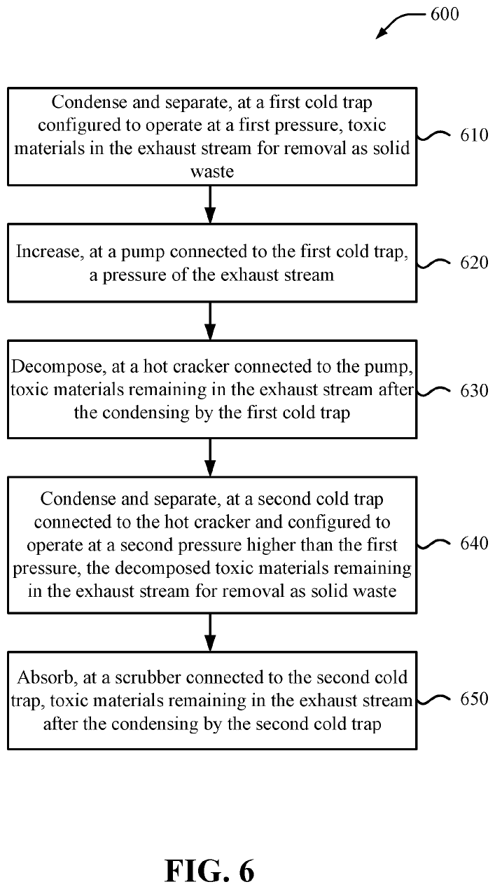

FIG. 6 is a flow chart that illustrates an example of a method 600 for MOCVD effluent abatement in accordance with aspects of this disclosure.

At block 610, the method 600 includes condensing and separating, at a first cold trap (e.g., low pressure cold trap 130, cold traps in FIGS. 4, 5) configured to operate at a first pressure, toxic materials in the exhaust stream for removal as solid waste.

At block 620, the method 600 includes increasing, at a pump (e.g., the pump 140) connected to the first cold trap, a pressure of the exhaust stream.

At block 630, the method 600 includes decomposing, at a hot cracker (e.g., the hot cracker 150 in FIGS. 1 and 2) connected to the pump, toxic materials remaining in the exhaust stream after the condensing by the first cold trap.

At block 640, the method 600 includes condensing and separating, at a second cold trap (e.g., the atmospheric pressure cold trap 160, cold traps in FIGS. 4, 5) connected to the hot cracker and configured to operate at a second pressure higher than the first pressure, the decomposed toxic materials remaining in the exhaust stream for removal as solid waste.

At block 650, the method 600 includes absorbing, at a scrubber (e.g., the scrubber 650) connected to the second cold trap, toxic materials remaining in the exhaust stream after the condensing by the second cold trap.

In another aspect of the method 600, the method 600 may further include removing, at a burn box (e.g., the burn box 180) connected to the scrubber, flammable gas (e.g., hydrogen) from the exhaust stream.

In another aspect of the method 600, wherein condensing and separating at the first cold trap or at the second cold trap includes performing a cyclone-based condensing operation and subsequently performing a cyclone-based separation operation. The cyclone-based separation operation can be a multi-stage operation that includes multiple, separate cyclone-based separations, and where each of these separations can be configured to separate particles of different types and/or sizes.

Although the present disclosure has been provided in accordance with the implementations shown, one of ordinary skill in the art will readily recognize that there could be variations to the embodiments and those variations would be within the scope of the present disclosure. Accordingly, many modifications may be made by one of ordinary skill in the art without departing from the scope of the appended claims.

What is claimed is:

1. A system for removing toxic waste from an exhaust stream produced by a high-volume metal organic chemical vapor deposition (MOCVD) operation, comprising:
a first cold trap configured to operate at a first pressure and condense and separate toxic materials in the exhaust stream for removal as solid waste;
a pump connected to the first cold trap and configured to increase a pressure of the exhaust stream;
a hot cracker connected to the pump and configured to decompose toxic materials remaining in the exhaust stream after the first cold trap;
a second cold trap connected to the hot cracker and configured to operate at a second pressure higher than the first pressure and condense the decomposed toxic materials remaining in the exhaust stream for removal as solid waste; and
a scrubber connected to the second cold trap and configured to absorb toxic materials remaining in the exhaust stream after the second cold trap.

2. The system of claim 1, further comprising a burn box connected to the scrubber and configured to remove flammable gas from the exhaust stream.

3. The system of claim 1, wherein the hot cracker includes a first section and a second section, the first section being an insulated thermal recuperator and the second section being a high-temperature cracking zone.

4. The system of claim 3, wherein the insulated thermal recuperator is configured to operate as a distributed heat exchange to heat up the exhaust stream provided to the hot cracker through an inlet and to cool down the exhaust stream after being processed by the high-temperature cracking zone and before being released through an outlet.

5. The system of claim 3, wherein the high-temperature cracking zone is configured to provide heat to decompose the toxic materials in the exhaust stream.

6. The system of claim 5, wherein the high-temperature cracking zone is further configured to include catalysts to decompose the toxic materials in the exhaust stream.

7. The system of claim 1, wherein each of the first cold trap and the second cold trap includes a first section and a second section, the first section including a condenser and the second section including a separator connected to the condenser.

8. The system of claim 7, wherein the condenser is configured to have a smooth, inverted sidewall.

9. The system of claim 7, wherein the first section further includes a cooling component surrounding an upper portion of the condenser and a heating component surrounding a lower portion of the condenser.

10. The system of claim 7, wherein the condenser is a cyclone condenser configured to generate a vortex to create homogeneous nucleation of the toxic materials that deposit on an inner wall of the condenser and heterogeneous nucleation of the toxic materials that remains in the exhaust stream as it is passed from the condenser to the separator.

11. The system of claim 10, wherein the first section further includes a removal component configured to remove the toxic materials deposited on the inner wall of the condenser by using one or both of a flash heating or sonic energy.

12. The system of claim 7, wherein the first section includes a removable component configure to collect condensed toxic materials produced by the condenser.

13. The system of claim 7, wherein the separator is a cyclone separator configured to generate a vortex to separate the toxic materials from the exhaust stream.

14. The system of claim 7, wherein the second section includes a removable component configured to collect toxic materials separated by the separator.

15. The system of claim 7, wherein the separator is positioned within the condenser.

16. The system of claim 15, further comprising a removable component configured to collect condensed toxic materials produced by the condenser and toxic materials separate by the separator.

17. The system of claim 1, wherein the hot cracker includes a high-temperature cracking zone having a thermal baffle with an inlet and an outlet, a diffuser, multiple heating rods, and a multiple pipes, the exhaust stream flowing into the thermal baffle through the inlet, the diffuser evenly distributing the exhaust stream between the multiple pipes, the multiple heating rods heating the multiple pipes and a thermal chamber formed by the thermal baffle, and the heated exhaust stream flowing out of the thermal baffle through the outlet.

18. A method for removing toxic waste from an exhaust stream produced by a high-volume metal organic chemical vapor deposition (MOCVD) operation, comprising:
condensing and separating, at a first cold trap configured to operate at a first pressure, toxic materials in the exhaust stream for removal as solid waste;
increasing, at a pump connected to the first cold trap, a pressure of the exhaust stream;
decomposing, at a hot cracker connected to the pump, toxic materials remaining in the exhaust stream after the condensing by the first cold trap;
condensing and separating, at a second cold trap connected to the hot cracker and configured to operate at a second pressure higher than the first pressure, the decomposed toxic materials remaining in the exhaust stream for removal as solid waste; and
absorbing, at a scrubber connected to the second cold trap, toxic materials remaining in the exhaust stream after the condensing by the second cold trap.

19. The method of claim 18, comprising removing, at a burn box connected to the scrubber, flammable gas from the exhaust stream.

20. The method of claim 18, wherein condensing and separating at the first cold trap or at the second cold trap includes performing a cyclone-based condensing operation and subsequently performing a cyclone-based separation operation.
